(19) United States
(12) Patent Application Publication
(10) Pub. No.: US 2012/0119357 A1
(43) Pub. Date: May 17, 2012

(54) SEMICONDUCTOR APPARATUS

(75) Inventors: Sang Jin Byeon, Ichon-si (KR); Tae Kyun Kim, Ichon-si (KR)

(73) Assignee: Hynix Semiconductor Inc., Ichon-si (KR)

(21) Appl. No.: 13/166,118

(22) Filed: Jun. 22, 2011

(30) Foreign Application Priority Data
Nov. 17, 2010 (KR) 10-2010-0114409

(51) Int. Cl. H01L 23/48; H01L 23/498

(52) U.S. Cl. 257/737; 257/774; 257/E23.011; 257/E23.068

(57) ABSTRACT

A semiconductor apparatus having stacked first and second chips includes a first through line of the first chip configured to receive a first coding signal and be electrically connected to a first through line of the second chip; a second through line of the first chip configured to receive a second coding signal; and a second through line of the second chip configured to be electrically connected to the first through line of the first chip and receive the first coding signal.

### CROSS-REFERENCES TO RELATED APPLICATION

The present application claims priority under 35 U.S.C. §119(a) to Korean Patent Application No. 10-2010-0114409, filed on Nov. 17, 2010, in the Korean Intellectual Property Office, which is incorporated herein by reference in its entirety as if set forth in full.

### BACKGROUND

1. Technical Field

Various embodiments of the present invention relate to semiconductor apparatuses. In particular, certain embodiments relate to a semiconductor apparatus having a plurality of chips that performs efficient assignment of IDs to the plurality of chips.

2. Related Art

In order to improve the degree of integration of a semiconductor apparatus, a 3D (three-dimensional) semiconductor apparatus, in which a plurality of chips are stacked and packaged in a single package to increase the degree of integration, has been developed. Since the 3D semiconductor apparatus includes the plurality of chips therein, the 3D semiconductor apparatus is configured such that the respective chips can be distinguished by electric signals that enable the semiconductor apparatus to select a certain chip among the respective chips.

FIG. 1 is a view schematically illustrating the configuration of a related art semiconductor apparatus including a chip selection circuit. As can be seen from FIG. 1, three chips Chip1 to Chip3 constituting the semiconductor apparatus are stacked in a misaligned step-like shape. The respective chips Chip1 to Chip3 have chip selection pins Chip Selection Pin 1 and Chip Selection Pin 2 for receiving chip selection signals. Two voltages VDD and VSS are applied to the respective chips Chip1 to Chip3 from the two chip selection pins Chip Selection Pin 1 and Chip Selection Pin 2. One of the three chips Chip1 to Chip3 may be selected based on the applied two voltages VDD and VSS. In the related art semiconductor apparatus, when the two chip selection pins Chip Selection Pin 1 and Chip Selection Pin 2 are provided for each chip as described above, up to four chips may be selected.

However, since the chip selection pins should be additionally provided as described above in the related-art semiconductor apparatus, it is difficult to secure the enough footage of the chips, and only a limited number of chips may be selected. Also, the semiconductor apparatus should be equipped with wires for connecting the voltages VDD and VSS with the chip selection pins Chip Selection Pin 1 and Chip Selection Pin 2, which makes the overall circuit wiring complicated. Further, since the chips should be stacked in a misaligned step-like shape, packaging the semiconductor apparatus is complex and difficult.

Recently, a 3D semiconductor apparatus using through-silicon vias (TSVs) has been developed. The 3D semiconductor apparatus may include a plurality of chips. The plurality of chips may be electrically connected to one another through TSVs. The semiconductor apparatus using the TSVs may be formed by stacking the chips of a same type or different types. In this regard, the semiconductor apparatus is typically formed by stacking at least one master chip and a plurality of slave chips with the same structure. The master chip may have the same or a different structure as the slave chips.

FIG. 2 is a view schematically illustrating the structure of a semiconductor apparatus using TSVs. As shown in FIG. 2, a master chip and a plurality of slave chips may be electrically connected to one another through TSVs. The plurality of slave chips receive the data signals in common which are transmitted from the master chip through the TSVs by receivers, and the signals transmitted from the respective slave chips by transceivers are received by the master chip through the TSVs. For example, when a signal is transmitted through the TSVs, all the slave chips receive the signal, which triggers all the slave chips to operate. Accordingly, a method for selecting only a slave chip that is intended to operate is necessary. By designating a slave chip which is intended to operate, only the slave chip to actually operate can receive the signal and then operate, while all the slave chips receive the signal from the master chip in common.

### SUMMARY

Accordingly, there is a need for an improved 3D semiconductor apparatus which is capable of efficiently assigning IDs to a plurality of chips therein.

To attain the advantages and in accordance with the purposes of the invention, as embodied and broadly described herein, one exemplary aspect of the present invention may provide a semiconductor apparatus having stacked first and second chips which includes: a first through line of the first chip configured to be electrically connected to a first through line of the second chip and receive a first coding signal; a second through line of the first chip configured to receive a second coding signal; and a second through line of the second chip configured to be electrically connected to the first through line of the first chip and receive the first coding signal.

In another exemplary aspect of the present invention, a semiconductor apparatus may include first to third chips each having first to third through lines, wherein each of the first to third chips receives a first coding signal through its first through line, and the second and third through lines of the first chip respectively transmit second and third coding signals, and wherein the second through line of the second chip is electrically connected to the first through line of the first chip and the third through line of the third chip, the third through line of the second chip is electrically connected to the second through line of the first chip, and the second through line of the third chip is electrically connected to the first through line of the second chip.

In still another exemplary aspect of the present invention, a semiconductor apparatus may have a plurality of stacked chips, and the plurality of chips may include a plurality of through lines which are arranged along the same vertical lines, and wherein one or more through lines of the plurality of through lines of one chip are electrically connected to one or more through lines of the plurality of through lines of another chip, which are not arranged along the same lines with the one or more through lines.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate various embodiments consistent with the invention and, together with the description, serve to explain the principles of the invention.

FIG. 1 is a view schematically illustrating the configuration of a related art semiconductor apparatus.

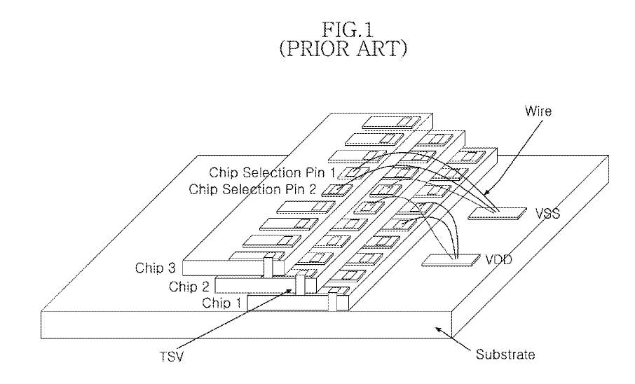

FIG. 2 is a view schematically illustrating the structure of a semiconductor apparatus using TSVs.

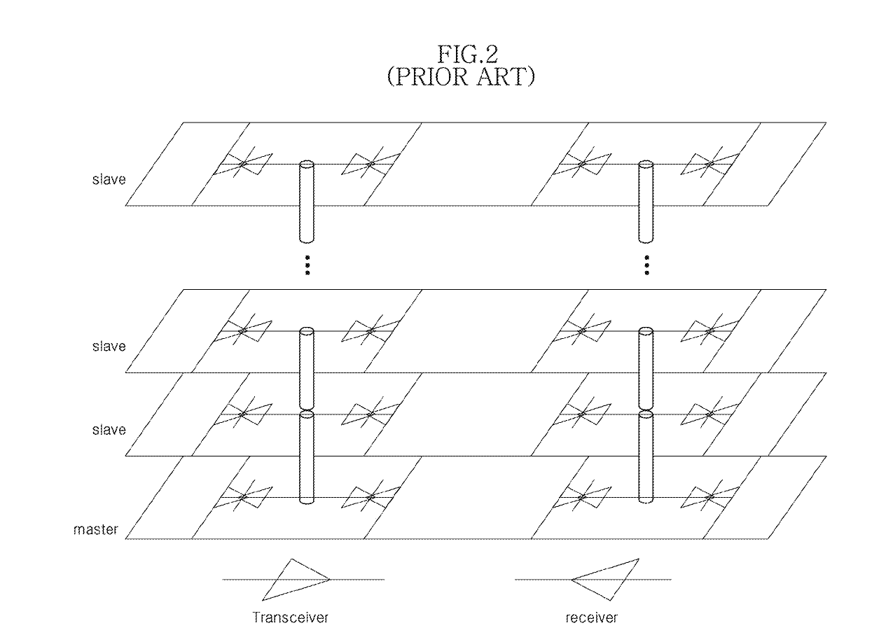

FIG. 3 is a view schematically illustrating the configuration of a semiconductor apparatus in accordance with an embodiment of the present invention.

FIG. 4 is a view illustrating how respective through lines are connected in series through first and second chips.

### DETAILED DESCRIPTION

Reference will now be made in detail to the exemplary embodiments consistent with the present disclosure, examples of which are illustrated in the accompanying drawings. Wherever possible, the same reference characters will be used throughout the drawings to refer to the same or like parts.

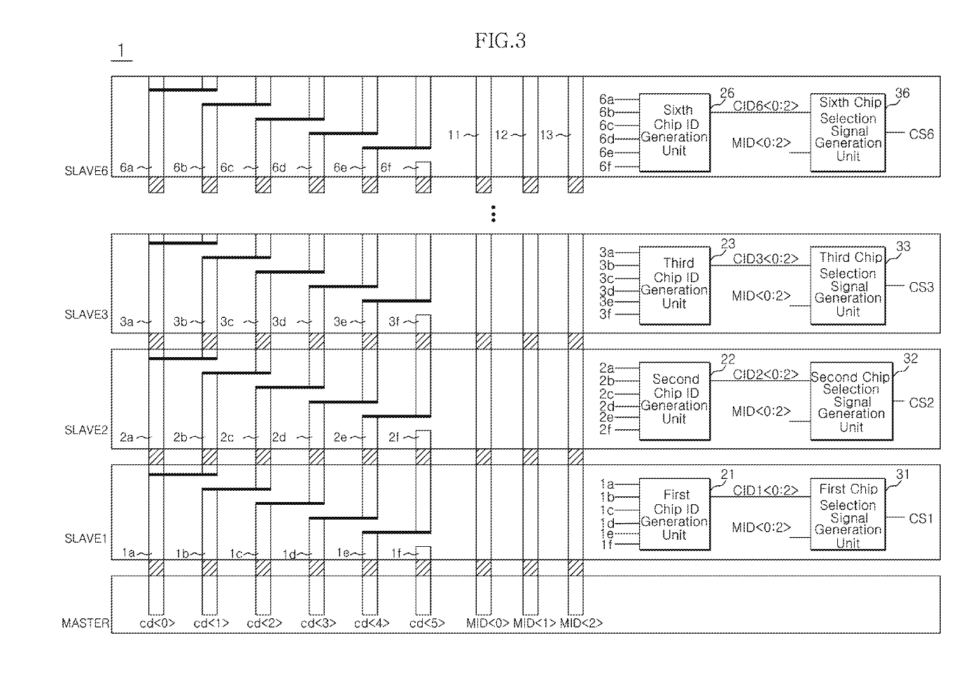

FIG. 3 is a view schematically illustrating the configuration of a semiconductor apparatus in accordance with an embodiment of the present invention. As shown in FIG. 3, the semiconductor memory apparatus may be a 3D semiconductor apparatus 1 including first to sixth chips SLAVE1 to SLAVE6 which are sequentially stacked. While the it is illustrated in FIG. 3 that the semiconductor memory apparatus 1 includes six slave chips SLAVE1 to SLAVE6, it is to be appreciated that the semiconductor memory apparatus 1 may include any number of slave chips without departing from the principle of the invention.

As shown in FIG. 3, the first to sixth chips SLAVE1 to SLAVE6 may respectively include first to sixth through lines 1a to 1f, 2a to 2f, 3a to 3f, 4a to 4f, 5a to 5f and 6a to 6f. The first to sixth through lines 1a to 1f of the first chip SLAVE1 may receive first to sixth coding signals cd<0:5>, respectively. The first through lines 1a, 2a, 3a, 4a, 5a and 6a of the first to sixth chips SLAVE1 to SLAVE6 are connected in parallel and transmit the first coding signal cd<0>. The through lines shown in FIG. 3 comprise through-silicon vias which are formed through the first to sixth chips SLAVE1 to SLAVE6. Since the through-silicon vias may be filled with a conductive material, the chips formed with the through-silicon vias may be electrically connected to one another.

The first through line 1a of the first chip SLAVE1 is electrically connected in series to the second through line 2b of the second chip SLAVE2, and the second through line 2b of the second chip SLAVE2 is electrically connected in series to the third through line 3c of the third chip SLAVE3. While not shown in the drawing, when considering the connection structure of the through lines of the first to third chips SLAVE1 to SLAVE3, the third through line 3c of the third chip SLAVE3 is electrically connected in series sequentially to the fourth through line 4d of the fourth chip SLAVE4, the fifth through line 5e of the fifth chip SLAVE5, and the sixth through line 6f of the sixth chip SLAVE6. Accordingly, the first through line 1a of the first chip SLAVE1, the second through line 2b of the second chip SLAVE2, the third through line 3c of the third chip SLAVE3, the fourth through line 4d of the fourth chip SLAVE4, the fifth through line 5e of the fifth chip SLAVE5, and the sixth through line 6f of the sixth chip SLAVE6 are connected in series and transmit the first coding signal cd<0>.

The second through line 1b of the first chip SLAVE1 is electrically connected in series to the third through line 2c of the second chip SLAVE2, the third through line 2c of the second chip SLAVE2 is electrically connected in series to the fourth through line 3d of the third chip SLAVE3, the fourth through line 3d of the third chip SLAVE3 is electrically connected in series to the fifth through line 4e of the fourth chip SLAVE4, and the fifth through line 4e of the fourth chip SLAVE4 is electrically connected in series to the sixth through line 5f of the fifth chip SLAVE5. Accordingly, the second through line 1b of the first chip SLAVE1, the third through line 2c of the second chip SLAVE2, the fourth through line 3d of the third chip SLAVE3, the fifth through line 4e of the fourth chip SLAVE4, and the sixth through line 5f of the fifth chip SLAVE5 are connected in series and transmit the second coding signal cd<1>.

The third through line 1c of the first chip SLAVE1 is electrically connected in series to the fourth through line 2d of the second chip SLAVE2, the fourth through line 2d of the second chip SLAVE2 is electrically connected in series to the fifth through line 3e of the third chip SLAVE3, and the fifth through line 3e of the third chip SLAVE3 is electrically connected in series to the sixth through line 4f of the fourth chip SLAVE4. Accordingly, the third through line 1c of the first chip SLAVE1, the fourth through line 2d of the second chip SLAVE2, the fifth through line 3e of the third chip SLAVE3, and the sixth through line 4f of the fourth chip SLAVE4 are connected in series and transmit the third coding signal cd<2>.

The fourth through line 1d of the first chip SLAVE1 is electrically connected in series to the fifth through line 2e of the second chip SLAVE2, and the fifth through line 2e of the second chip SLAVE2 is electrically connected in series to the sixth through line 3f of the third chip SLAVE3. Accordingly, the fourth through line 1d of the first chip SLAVE1, the fifth through line 2e of the second chip SLAVE2, and the sixth through line 3f of the third chip SLAVE3 are connected in series and transmit the fourth coding signal cd<3>.

The fifth through line 1e of the first chip SLAVE1 is electrically connected in series to the sixth through line 2f of the second chip SLAVE2. Accordingly, the fifth through line 1e of the first chip SLAVE1 and the sixth through line 2f of the second chip SLAVE2 transmit the fifth coding signal <4>.

The second through line 3b of the third chip SLAVE3 is electrically connected in series to the first through line 2a of the second chip SLAVE2. The second through line 3b of the third chip SLAVE3 is also electrically connected in series to the third through line 4c of the fourth chip SLAVE4. The third through line 4c of the fourth chip SLAVE4 is electrically connected in series to the fourth through line 5d of the fifth chip SLAVE5, and the fourth through line 5d of the fifth chip SLAVE5 is electrically connected in series to the fifth through line 6e of the sixth chip SLAVE6. Accordingly, the second through line 3b of the third chip SLAVE3, the third through line 4c of the fourth chip SLAVE4, the fourth through line 5d of the fifth chip SLAVE5, and the fifth through line 6e of the sixth chip SLAVE6 are connected in series and transmit the first coding signal cd<0>.

The second through line 4b of the fourth chip SLAVE4 is electrically connected in series to the first through line 3a of the third chip SLAVE3. The second through line 4b of the fourth chip SLAVE4 is also electrically connected in series to the third through line 5c of the fifth chip SLAVE5. The third through line 5c of the fifth chip SLAVE5 is electrically connected in series to the fourth through line 6d of the sixth chip SLAVE6. Accordingly, the second through line 4b of the fourth chip SLAVE4, the third through line 5c of the fifth chip SLAVE5, and the fourth through line 6d of the sixth chip SLAVE6 are connected in series and transmit the first coding signal cd<0>.

The second through line 5b of the fifth chip SLAVE5 is electrically connected in series to the first through line 4a of the fourth chip SLAVE4. The second through line 5b of the fifth chip SLAVE5 is also electrically connected in series to the third through line 6c of the sixth chip SLAVE6. Accordingly, the second through line 5b of the fifth chip SLAVE5 and the third through line 6c of the sixth chip SLAVE6 are connected in series and transmit the first coding signal cd<0>.

The second through line 6b of the sixth chip SLAVE6 is electrically connected to the first through line 5a of the fifth chip SLAVE5 and transmits the first coding signal cd<0>.

Referring again to FIG. 3, the first through lines 1a, 2a, 3a, 4a, 5a and 6a of the first to sixth chips SLAVE1 to SLAVE6 are connected in parallel with one another, and the first through lines 1a, 2a, 3a, 4a and 5a of the first to fifth chips SLAVE1 to SLAVE5 are connected in series to the second through lines 2b, 3b, 4b, 5b and 6b of the second to sixth chips SLAVE2 to SLAVE6, respectively. The second through lines 1b, 2b, 3b, 4b and 5b of the first to fifth chips SLAVE1 to SLAVE5 are connected in series to the third through lines 2c, 3c, 4c, 5c and 6c of the second to sixth chips SLAVE2 to SLAVE6, respectively. As the through lines of the respective chips of the semiconductor apparatus 1 are formed in this way, all the chips constituting the semiconductor apparatus 1 may have the same structure. The connection of the through lines in accordance with the embodiment of the present invention is made possible by redistribution layers which will be described later.

As shown in FIG. 3, the semiconductor apparatus 1 in accordance with the embodiment of the present invention may further include first to sixth chip ID generation units 21 to 26 and first to sixth chip selection signal generation units 31 to 36. The first to sixth chip ID generation units 21 to 26 may be respectively disposed in the first to sixth chips SLAVE1 to SLAVE6. The first chip ID generation unit 21 may be configured to receive the signals transmitted through the first to sixth through lines 1a to 1f of the first chip SLAVE1 and generate a first chip ID signal CID1<0:2>. The second to sixth chip ID generation units 22 to 26 may be configured to receive the signals transmitted through the first to sixth through lines 2a to 2f, 3a to 3f, 4a to 4f, 5a to 5f and 6a to 6f of the second to sixth chips SLAVE2 to SLAVE6. The first to sixth chip ID generation units 21 to 26 may be configured using decoding units which are generally known in the art, to decode the signals transmitted through the corresponding through lines.

While it is exemplified that the first to sixth chip ID generation units 21 to 26 receive 6-bit signals from the six through lines of the respective chips and generate 3-bit chip ID signals, the present invention is not limited to such an exemplary embodiment, and it is to be noted that the number of bits may be regulated and changed in a variety of ways depending upon the number of chips, the number of through lines and the bit number of chip ID signals to be generated.

The first to sixth chip selection signal generation units 31 to 36 may be respectively disposed in the first to sixth chips SLAVE1 to SLAVE6. Each of the first to sixth chip selection signal generation units 31 to 36 may receive a main ID signal MID<0:2>. The first to sixth chip selection signal generation units 31 to 36 may be configured to receive the respective corresponding chip ID signals CID1<0:2> to CID6<0:2> and the main ID signal MID<0:2> and generate first to sixth chip selection signals CS1 to CS6 when the main ID signal MID<0:2> and the respective chip ID signals CID1<0:2> to CID6<0:2> match each other. The first to sixth chip selection signals CS1 to CS6 are signals to activate the first to sixth chips SLAVE1 to SLAVE6. A certain chip with one of the chip ID signals CID1<0:2> to CID6<0:2> which match the main ID signal MID<0:2> may be activated and operated.

The main ID signal MID<0:2> may be respectively transmitted to the first to sixth chips SLAVE1 to SLAVE6 through main through lines 11 to 13. Since the chip ID signal CID<0:2> is exemplified as a 3-bit signal in the embodiment of the present invention, the main ID signal MID<0:2> is also exemplified as a 3-bit signal. Accordingly, the main ID signal MID<0:2> may be transmitted through the three main through lines 11 to 13.

In FIG. 3, the semiconductor apparatus 1 in accordance with the embodiment of the present invention may further include a master chip MASTER. The master chip MASTER may be configured to provide the first to sixth coding signals cd<0:5>, and receive the main ID signal MID<0:2> from a controller outside the semiconductor apparatus 1 and transmit the main ID signal MID<0:2> to the main through lines 11 to 13.

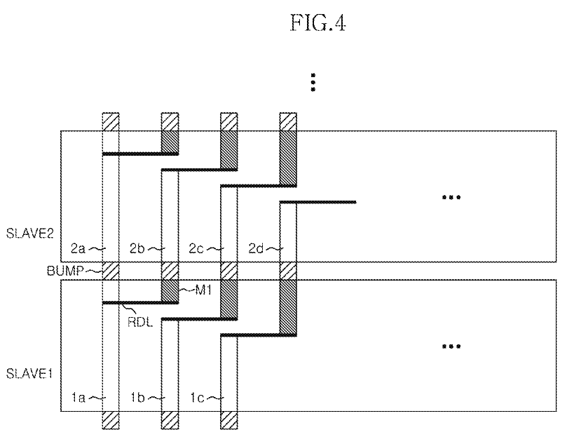

FIG. 4 illustrates a structure in which the through lines 1a to 1c and 2a to 2d of the first and second chips SLAVE1 and SLAVE2 are connected. FIG. 4 illustrates, in an enlarged state, the connections of the through lines of the first and second chips SLAVE1 and SLAVE2. Referring to FIG. 4, bumps BUMP are disposed between the first and second chips SLAVE1 and SLAVE2 to connect the respective through lines thereof. A redistribution layer RDL is formed on the first through line 1a of the first chip SLAVE1 to extend from the first through line 1a toward the second through line 1b. The redistribution layer RDL is formed of a conductive material such as a metal line. The redistribution layer RDL is connected to a metal line M1, and the metal line M1 is connected to the second through line 2b of the second chip SLAVE2 through the bump BUMP. Accordingly, the first through line 1a of the first chip SLAVE1 may be electrically connected to the second through line 2b of the second chip SLAVE2. Similarly, the second through line 2b of the second chip SLAVE2 may be connected to a redistribution layer RDL, the redistribution layer RDL may be connected to a metal line M1, and the metal line M1 may be connected to the third through line 3c of the third chip SLAVE3 (see FIG. 3). Similarly, the second through line 1b of the first chip SLAVE1 may be connected to a redistribution layer RDL, and the redistribution layer RDL may be connected to the third through line 2c of the second chip SLAVE2 through a metal line M1 and the bump BUMP. In this structure, the through lines 1a to 1c and 2a to 2d of the first and second chips SLAVE1 and SLAVE2 may be electrically connected in series to through lines which are disposed along different vertical lines.

While the connection points where the through lines meet each other are illustrated to be different from one another in FIG. 4 because the structures of the three-dimensional chips are illustrated in a plane, the figure is given for the sake of illustration and should not be construed as a limiting manner. Further, while not shown in the drawings, for example, it is conceivable that the redistribution layer RDL, which is connected to the first through line 1a of the first chip SLAVE1, may be configured to be connected to the first through line 1a of the first chip SLAVE1 by using another metal line and another bump.

By connecting the through lines as shown in FIG. 4, serial connection of the through lines not disposed along the same vertical lines is made possible, and therefore, all the chips constituting the semiconductor apparatus 1 may have the same structure. Also, even though chips with the same structure are stacked, it is possible to assign different IDs to the respective chips by transmitting the coding signals.

Operations of the semiconductor apparatus 1 in accordance with the embodiment of the present invention will be described below with reference to FIG. 3. As the first to sixth coding signals cd<0:5> are applied to the semiconductor apparatus 1, the first to sixth through lines 1a to 1f, 2a to 2f, 3a to 3f, 4a to 4f, 5a to 5f and 6a to 6f of the first to sixth chips SLAVE1 to SLAVE6 transmit corresponding coding signals. For example, if the first coding signal cd<0> has a logic level of 1 and the second to sixth coding signals cd<1:5> have logic levels of 0, the first coding signal cd<0> with the logic level of 1 is transmitted through the first through lines 1a to 6a of the first to sixth chips SLAVE1 to SLAVE6. Also, the coding signal cd<0> with the logic level of 1 is transmitted sequentially through the second through line 2b of the second chip SLAVE2, the third through line 3c of the third chip SLAVE3, the fourth through line 4d of the fourth chip SLAVE4, the fifth through line 5e of the fifth chip SLAVE5 and the sixth through line 6f of the sixth chip SLAVE6, which are sequentially connected in series to the first through line 1a of the first chip SLAVE1. Further, all of the second through line 3b of the third chip SLAVE3, the third through line 4c of the fourth chip SLAVE4, the fourth through line 5d of the fifth chip SLAVE5 and the fifth through line 6e of the sixth chip SLAVE6 which are sequentially connected in series to the first through line 2a of the second chip SLAVE2, the second through line 4b of the fourth chip SLAVE4, the third through line 5c of the fifth chip SLAVE5 and the fourth through line 6d of the sixth chip SLAVE6 which are sequentially connected in series to the first through line 3a of the third chip SLAVE3, the second through line 5b of the fifth chip SLAVE5 and the third through line 6c of the sixth chip SLAVE6 which are sequentially connected in series to the first through line 4a of the fourth chip SLAVE4, and the second through line 6b of the sixth chip SLAVE6 which is connected in series to the first through line 5a of the fifth chip SLAVE5, transmit the first coding signal cd<0>.

The third through line 2c of the second chip SLAVE2, the fourth through line 3d of the third chip SLAVE3, the fifth through line 4e of the fourth chip SLAVE4 and the sixth through line 5f of the fifth chip SLAVE5, which are sequentially connected in series to the second through line 1b of the first chip SLAVE1, transmit the second coding signal cd<1> with the logic level of 0.

The fourth through line 2d of the second chip SLAVE2, the fifth through line 3e of the third chip SLAVE3 and the sixth through line 4f of the fourth chip SLAVE4, which are sequentially connected in series to the third through line 1c of the first chip SLAVE1, transmit the third coding signal cd<2> with the logic level of 0.

The fifth through line 2e of the second chip SLAVE2 and the sixth through line 3f of the third chip SLAVE3, which are sequentially connected in series to the fourth through line 1d of the first chip SLAVE1, transmit the fourth coding signal cd<3> with the logic level of 0.

The sixth through line 2f of the second chip SLAVE2, which is connected in series to the fifth through line 1e of the first chip SLAVE1, transmits the fifth coding signal cd<4> with the logic level of 0. The sixth coding signal cd<5> is transmitted only through the sixth through line 1f of the first chip SLAVE1.

Accordingly, as the first to sixth coding signals cd<0:5> with the logic levels of 100000 are transmitted through the first to sixth through lines 1a to 1f of the first chip SLAVE1, the signals transmitted through the first to sixth through lines 2a to 2f of the second chip SLAVE2 have the logic levels of 110000, the signals transmitted through the first to sixth through lines 3a to 3f of the third chip SLAVE3 have the logic levels of 111000, the signals transmitted through the first to sixth through lines 4a to 4f of the fourth chip SLAVE4 have the logic levels of 111100, the signals transmitted through the first to sixth through lines 5a to 5f of the fifth chip SLAVE5 have the logic levels of 111110, and the signals transmitted through the first to sixth through lines 6a to 6f of the sixth chip SLAVE6 have the logic levels of 111111. Accordingly, if the first to sixth coding signals cd<0:5> are transmitted through the connection structure of the through lines, signals with different logic levels may be transmitted to the first to sixth chips SLAVE1 to SLAVE6, respectively.

The first chip ID generation unit 21 receives the signals with the logic levels of 100000 which are transmitted through the first to sixth through lines 1a to 1f of the first chip SLAVE1 and generates a first chip ID signal CID1<0:2>, and the second chip ID generation unit 22 receives the signals with the logic levels of 110000 which are transmitted through the first to sixth through lines 2a to 2f of the second chip SLAVE2 and generates a second chip ID signal CID2<0:2>. Similarly, the third to sixth chip ID generation units 23 to 26 receive the signals transmitted through the first to sixth through lines 3a to 3f, 4a to 4f, 5a to 5f and 6a to 6f of the respective chips, and generate third to sixth chip ID signals CID3<0:2> to CID6<0:2>.

For example, it is assumed that the first to sixth chip ID signals CID1<0:2> to CID6<0:2>, which are generated by the first to sixth chip ID generation units 21 to 26, respectively have logic levels of 001, 010, 011, 100, 101 and 110. The master chip MASTER receives the main ID signal MID<0:2> from the controller outside the semiconductor apparatus 1. The main ID signal MID<0:2> is transmitted to the first to sixth chips SLAVE1 to SLAVE6 through the main through lines 11 to 13. The first to sixth selection signal generation units 31 through 36 compare the respective first to sixth chip ID signals CID1<0:2> to CID6<0:2> and the main ID signal MID<0:2>.

If the main ID signal MID<0:2> is a signal which has the logic level of 010, since the main ID signal MID<0:2> matches the second chip ID signal CID2<0:2>, the second chip selection signal generation unit 32 may generate the second chip selection signal CS2 and activate the second chip SLAVE2. Accordingly, operations of the semiconductor apparatus 1 may be performed by the second chip SLAVE2.

While certain embodiments have been described above, it will be understood to those skilled in the art that the embodiments described are by way of example only. Accordingly, the semiconductor apparatus described herein should not be limited based on the described embodiments. Rather, the semiconductor apparatus described herein should only be limited in light of the claims that follow when taken in conjunction with the above description and accompanying drawings.

What is claimed is:

1. A semiconductor apparatus having stacked first and second chips, comprising:
a first through line of the first chip configured to be electrically connected to a first through line of the second chip and receive a first coding signal;
a second through line of the first chip configured to receive a second coding signal; and
a second through line of the second chip configured to be electrically connected to the first through line of the first chip and receive the first coding signal.

2. The semiconductor apparatus according to claim 1, further comprising a third through line of the second chip configured to be electrically connected to the second through line of the first chip and receive the second coding signal.

3. The semiconductor apparatus according to claim 2, further comprising:
a third through line of the first chip configured to receive a third coding signal;
a first chip ID generation unit configured to receive signals transmitted through the first to third through lines of the first chip and generate a first chip ID signal; and
a second chip ID generation unit configured to receive signals transmitted through the first to third through lines of the second chip and generate a second chip ID signal.

4. The semiconductor apparatus according to claim 3, further comprising:
main through lines configured to be electrically connected through the first and second chips and transmit a main ID signal.

5. The semiconductor apparatus according to claim 4, further comprising:
a first chip selection signal generation unit configured to be disposed in the first chip and generate a first chip selection signal for activating the first chip, depending upon whether the first chip ID signal matches the main ID signal.

6. The semiconductor apparatus according to claim 5, further comprising:
a second chip selection signal generation unit configured to be disposed in the second chip and generate a second chip selection signal for activating the second chip, depending upon whether the second chip ID signal matches the main ID signal.

7. The semiconductor apparatus according to claim 1, wherein the first through line of the first chip is electrically connected to the second through line of the second chip by way of a first redistribution layer which is disposed on the first chip.

8. The semiconductor apparatus according to claim 7, wherein the first redistribution layer is connected to the second through line of the second chip by way of a metal line and a bump.

9. The semiconductor apparatus according to claim 2, wherein the second through line of the first chip is connected to the third through line of the second chip by way of a second redistribution layer which is disposed on the first chip.

10. The semiconductor apparatus according to claim 9, wherein the second redistribution layer is connected to the third through line of the second chip by way of a metal line and a bump.

11. A semiconductor apparatus including first to third chips each having first to third through lines,
wherein each of the first to third chips receives a first coding signal through its first through line, and the second and third through lines of the first chip respectively transmit second and third coding signals, and
wherein the second through line of the second chip is electrically connected to the first through line of the first chip and the third through line of the third chip, the third through line of the second chip is electrically connected to the second through line of the first chip, and the second through line of the third chip is electrically connected to the first through line of the second chip.

12. The semiconductor apparatus according to claim 11, further comprising:
a first chip ID generation unit configured to receive signals transmitted through the first to third through lines of the first chip and generate a first chip ID signal;
a second chip ID generation unit configured to receive signals transmitted through the first to third through lines of the second chip and generate a second chip ID signal; and
a third chip ID generation unit configured to receive signals transmitted through the first to third through lines of the third chip and generate a third chip ID signal.

13. The semiconductor apparatus according to claim 12, further comprising:
main through lines configured to electrically connecting the first to third chips and transmit a main ID signal.

14. The semiconductor apparatus according to claim 13, further comprising:
a first chip selection signal generation unit configured to generate a first chip selection signal depending upon whether the first chip ID signal matches the main ID signal;
a second chip selection signal generation unit configured to generate a second chip selection signal depending upon whether the second chip ID signal matches the main ID signal; and
a third chip selection signal generation unit configured to generate a third chip selection signal depending upon whether the third chip ID signal matches the main ID signal.

15. The semiconductor apparatus according to claim 11, wherein the second through line of the second chip is connected in series to the first through line of the first chip by way of a redistribution layer which is disposed on the first chip.

16. The semiconductor apparatus according to claim 13, wherein the second through line of the second chip is connected in series to the third through line of the third chip by way of a redistribution layer which is disposed on the second chip.

17. The semiconductor apparatus according to claim 11, wherein the third through line of the second chip is connected in series to the second through line of the first chip by way of a redistribution layer which is disposed on the first chip.

18. The semiconductor apparatus according to claim 11, wherein the second through line of the third chip is connected in series to the first through line of the second chip by way of a redistribution layer which is disposed on the second chip.

19. A semiconductor apparatus having a plurality of stacked chips,
wherein the plurality of chips include a plurality of through lines which are arranged along the same vertical lines, and
wherein one or more through lines of the plurality of through lines of one chip are electrically connected to one or more through lines of the plurality of through lines of another chip, which are not arranged along the same lines with the one or more through lines.

20. The semiconductor apparatus according to claim 19, wherein connections between the one or more through lines of the one chip and the one or more through lines of another chip are formed through redistribution layers.

21. The semiconductor apparatus according to claim 20, further comprising:
metal lines and bumps connected between the redistribution layers and the one or more through lines of the one chip and the one or more through lines of another chip.
